(19) United States
(12) Patent Application Publication
(10) Pub. No.: US 2014/0034836 A1
(43) Pub. Date: Feb. 6, 2014

(54) RADIATION DETECTION APPARATUS, MANUFACTURING METHOD THEREOF, AND RADIATION DETECTION SYSTEM

(71) Applicant: CANON KABUSHIKI KAISHA, Tokyo (JP)

(72) Inventors: Taiki Takei, Okegawa-shi (JP); Masato Inoue, Kumagaya-shi (JP); Shinichi Takeda, Honjo-shi (JP); Satoru Sawada, Fujioka-shi (JP); Takamasa Ishii, Honjo-shi (JP); Kota Nishibe, Honjo-shi (JP); Shoshiro Saruta, Kodama-gun (JP); Kazumi Nagano, Honjo-shi (JP); Satoshi Okada, Tokyo (JP); Yohei Ishida, Honjo-shi (JP)

(73) Assignee: CANON KABUSHIKI KAISHA, Tokyo (JP)

(21) Appl. No.: 13/945,061

(22) Filed: Jul. 18, 2013

(30) Foreign Application Priority Data
Jul. 31, 2012 (JP) 2012-170377
Jul. 17, 2013 (JP) 2013-148831

(51) Int. Cl. G01T 1/20; H01L 27/144

(52) U.S. Cl. CPC G01T 1/2006; H01L 27/144
USPC 250/366; 250/361 R; 438/73

(57) ABSTRACT

A radiation detection apparatus includes a sensor panel configured to detect light; and a scintillator layer arranged on the sensor panel. The scintillator layer has a scintillator configured to convert radiation into light of a wavelength that is detectable by the sensor panel. The scintillator layer also has particles that have a property of generating a bubble and expanding so as to weaken adhesive force between the sensor panel and the scintillator layer. The scintillator layer also a resin that holds the scintillator and the particles so as to be mixed together. The scintillator layer is adhered to the sensor panel with use of the resin.

### BACKGROUND OF THE INVENTION

1. Field of the Invention

The present invention relates to a radiation detection apparatus, a manufacturing method thereof, and a radiation detection system.

2. Description of the Related Art

Methods of manufacturing a radiation detection apparatus that includes a sensor panel for detecting light and a scintillator layer for converting radiation into light are divided into two main types. One type is a manufacturing method called “direct type”, in which the scintillator layer is formed directly on the sensor panel by vapor deposition, coating, or the like. The other type is a manufacturing method called “indirect type”, in which a scintillator panel obtained by forming a scintillator layer on a substrate is bonded to the sensor panel with an adhesive or the like. In the direct manufacturing method described in Japanese Patent Laid-Open No. 2002-286846, a sensor panel is coated with a paste obtained by mixing an organic resin and a scintillator into an organic solvent, and a scintillator layer is formed by then drying the paste. This scintillator layer adheres to the sensor panel due to the adhesive force of the organic resin.

### SUMMARY OF THE INVENTION

According to a first aspect, a radiation detection apparatus includes a sensor panel configured to detect light, and a scintillator layer arranged on the sensor panel. The scintillator layer has a scintillator configured to convert radiation into light of a wavelength that is detectable by the sensor panel, particles that have a property of generating a bubble and expanding so as to weaken adhesive force between the sensor panel and the scintillator layer, and a resin that holds the scintillator and the particles so as to be mixed together. The scintillator layer is adhered to the sensor panel with use of the resin.

According to a second aspect, a method of manufacturing a radiation detection apparatus includes preparing a sensor panel configured to detect light, and forming a scintillator layer directly on the sensor panel. The scintillator layer has a scintillator configured to convert radiation into light of a wavelength that is detectable by the sensor panel, particles that have a property of generating bubbles and expanding so as to weaken adhesive force between the sensor panel and the scintillator layer, and a resin that holds the scintillator and the particles so as to be mixed together. In the forming, the scintillator layer is adhered to the sensor panel with use of the resin.

According to a third aspect, a radiation detection system includes the radiation detection apparatus described above, and a processing unit configured to process a signal from the radiation detection apparatus.

Further features of the present disclosure will become apparent from the following description of exemplary embodiments (with reference to the attached drawings).

### BRIEF DESCRIPTION OF THE DRAWINGS

The accompanying drawings, which are incorporated in and constitute a part of the specification, illustrate embodiments of the invention, and together with the description, serve to explain the principles of the embodiments.

FIG. 1 is a diagram for describing an example of a structure of a radiation detection apparatus according to some embodiments of the present invention.

FIGS. 2A and 2B are diagrams for describing examples of structures of a sensor panel according to some embodiments of the present invention.

FIG. 3 is a diagram for describing an example of a structure of a pixel according to some embodiments of the present invention.

FIGS. 4A and 4B are diagrams for describing an example of a method of manufacturing the radiation detection apparatus according to some embodiments of the present invention.

FIG. 5 is a diagram for describing an example of a method of manufacturing the radiation detection apparatus according to some embodiments of the present invention.

FIGS. 6A and 6B are diagrams for describing an example of a structure of the radiation detection apparatus according to some other embodiments of the present invention.

FIGS. 7A to 7C are diagrams for describing an example of a method for manufacturing a radiation detection apparatus according to some other embodiments of the present invention.

FIG. 8 is a diagram for describing an example of a structure of a radiation detection system according to some embodiments of the present invention.

### DESCRIPTION OF THE EMBODIMENTS

While the present invention will now be described with reference to exemplary embodiments, it is to be understood that the invention is not limited to the disclosed exemplary embodiments. The scope of the following claims is to be accorded the broadest interpretation so as to encompass all such modifications and equivalent structures and functions.

When forming a scintillator layer on a sensor panel, there are cases in which the scintillator layer includes foreign material, air bubbles, or the like. Thus, if a defect occurs in only the scintillator layer, the scintillator layer is separated from the sensor panel and the sensor panel is re-used. However, since the resin included in the scintillator layer has a strong adhesive force, there are cases in which the sensor panel is damaged if the scintillator layer is separated from the sensor panel. In view of this, some embodiments provide a technique for enabling easy separation of a scintillator layer formed directly on a sensor panel.

Embodiments of the present invention will be described below with reference to the accompanying drawings. Elements that are similar in various embodiments have identical reference numerals, and a description thereof will not be repeated. Also, the embodiments can be changed or combined as appropriate. Some embodiments of the present invention relate to a radiation detection apparatus that includes a sensor panel that detects light, and a scintillator layer that is formed on the sensor panel, and that converts radiation into light of a wavelength that is detectable by the sensor panel.

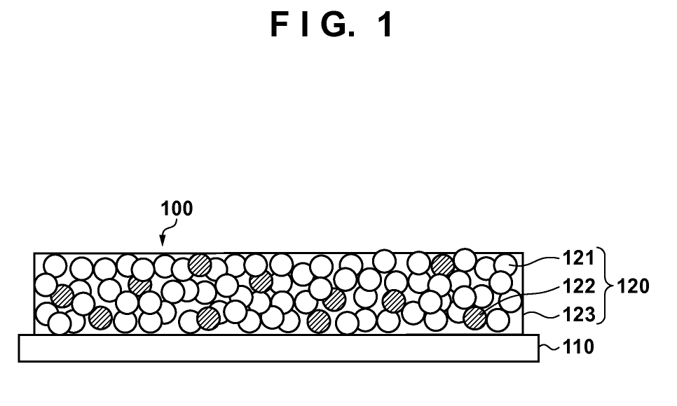

A structure of a radiation detection apparatus 100 of some embodiments of the present invention will be described below with reference to FIG. 1. The radiation detection apparatus 100 has a sensor panel 110 and a scintillator layer 120, and FIG. 1 shows a cross-sectional view of them. The scintillator layer 120 is formed directly on the sensor panel 110. Here, “formed directly” means that no other constituent elements, such as an adhesive layer or the like, are included between the sensor panel 110 and the scintillator layer 120 in order to bond them together. Although not shown in FIG. 1, the radiation detection apparatus 100 may include other constituent elements, such as a protection layer for covering the sides and upper surface of the scintillator layer 120 and improving moisture resistance of the scintillator layer 120, a reflection layer that guides light generated by the scintillator layer 120 to the sensor panel 110, or the like.

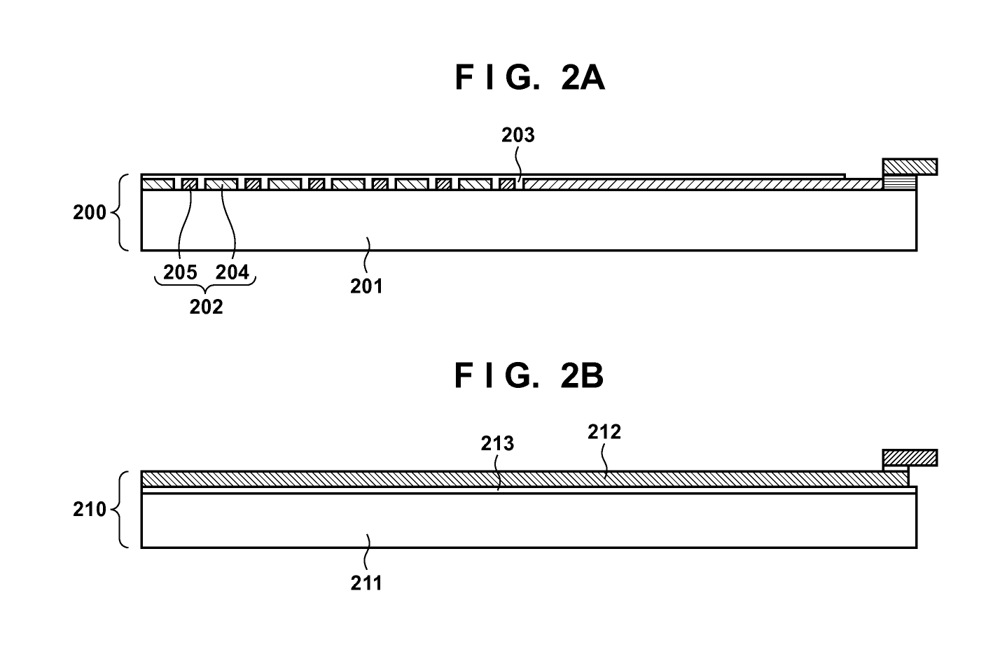

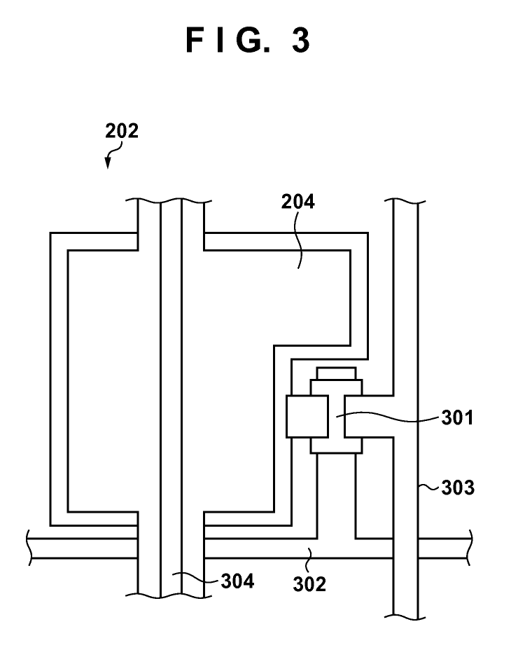

The sensor panel 110 may have any kind of configuration, as long as it can detect light. Here, examples of structures of the sensor panel 110 will be described with reference to FIGS. 2A, 2B, and FIG. 3. FIG. 2A is a cross-sectional view for describing a structure of a sensor panel 200 that can be used as the sensor panel 110. The sensor panel 200 can include a substrate 201, pixels 202, and a sensor protection layer 203. The substrate 201 is formed with a material such as glass, heat-resistant plastic, or the like, and multiple pixels 202 are arranged in an array on the substrate 201, configuring a pixel array. The pixels 202 can each include a photoelectric converter 204 that functions as a photoelectric conversion unit for converting light into a charge, and a circuit 205 that includes a TFT, a conduction line, and the like for reading out the charge. The photoelectric converter 204 can be formed using amorphous silicon for example, and can be in a configuration such as a MIS-type sensor, a PIN-type sensor, a TFT-type sensor, or the like. The sensor panel 110 may include, on the outside of the pixel array, a driving circuit for driving the circuit 205 and a signal processing circuit for processing signals from the pixel array. The sensor protection layer 203 covers and protects the pixels 202, and is formed with an inorganic material such as SiN, SiO₂, or the like. The scintillator layer 120 is formed at a position that covers the pixel array of the sensor panel 200.

FIG. 2B is a cross-sectional view for describing a structure of another sensor panel 210 that can be used as the sensor panel 110. The sensor panel 210 can be formed by bonding a base 211 and a sensor substrate 212, on which a pixel array is formed, together with an adhesive 213 or the like. The pixel array of the sensor substrate 212 may be in a configuration similar to that of the pixel array of the sensor panel 200 in FIG. 2A.

FIG. 3 is a plan view for describing an example of a structure of a pixel 202. The pixels 202 can each include a TFT 301, a gate line 302, and a signal line 303, which function as the aforementioned circuit 205. The TFT 301 reads out charge generated by the photoelectric converter 204, or amplification signals that are based on the charge. The gate line 302 is used for supplying, to the gate of the TFT 301, a driving signal for switching the TFT 301 on/off. The signal line 303 is used for reading out electrical signals and the like from the photoelectric converter 204 to an external signal processing unit. Also, the pixels 202 may have a common reset line 304 that is used for resetting the charge of the photoelectric converter 204.

A configuration of the scintillator layer 120 will be described in detail below with reference to FIG. 1 once again. The scintillator layer 120 can include a scintillator 121, particles 122, and a resin 123. The scintillator 121 and the particles 122 are mixed together in the scintillator layer 120 and are held by the resin 123.

The scintillator 121 converts radiation into light of a wavelength that is detectable by the photoelectric converter 204. In some embodiments of the present invention, the scintillator 121 is in particle form, and the particle size thereof is 1 to 30 μm. Here, “particle size” is a convenient value corresponding to the diameter when the particle is assumed to be a perfect sphere. The particle size may be measured using a Coulter counter method, or a laser diffraction/dispersion method (micro-track method).

The particle size of the particles 122 below is measured similarly. Materials such as a material obtained by doping gadolinium oxysulfide (Gd₂O₂S) with terbium (Tb) can be used as the material for the scintillator 121. Also, an alkali halide material typified by a material obtained by doping cesium iodide (CsI) with thallium (Tl) may be used as the scintillator 121.

The particles 122 are heat-expandable particles, and have a property of generating bubbles and expanding upon being heated. The adhesive force between the sensor panel 110 and the scintillator layer 120 is weakened by expansion of the particles 122, and thus the scintillator layer 120 can be easily separated from the sensor panel 110. For example, the particles 122 are micro-encapsulated bubble-generating agents whose volume expands by a factor of 5 to 10 if heated to a prescribed temperature or above. As this type of bubble-generating agent, it is possible to use microspheres, which are obtained by a substance that is gasified and expands easily upon being heated, such as isobutene, pentane, propane, or the like, being included inside elastic capsules. Capsules of the particles 122 can be formed by a thermo-plastic substance, a thermo-fusible substance, a substance that bursts due to thermal expansion, or the like. For example, vinylidene chloride acrylonitrile copolymer, polyvinyl alcohol, polyvinyl butyral, polymethyl methacrylate, polyacrylonitrile, polyvinylidene chloride, polysulfone, or the like may be used as the substance that forms the capsule of each of the particles 122. The particles 122 can be manufactured using coacervation, interfacial polymerization, or the like.

An inorganic bubble-generating agent may be used as the material of the particle 122. Ammonium carbonate, ammonium hydrogen carbonate, sodium hydrogen carbonate, ammonium nitrite, sodium borohydride, an azide, or the like may be used as the inorganic bubble-generating agent.

Commercial products may be used as the particles 122. “Matsumoto Microsphere F-30”, “Matsumoto Microsphere F-50”, “Matsumoto Microsphere F-80S”, or “Matsumoto Microsphere F-85” (manufactured by Matsumoto Yushi-Seiyaku Co., Ltd.) may be used for example. Also, the product named “Expancel Du” (manufactured by Akzo Nobel Surface Chemistry AB) or the like may be used.

Alternatively, in some other embodiments, water-absorbing particles that generate a bubble or that swell due to water absorption may be used as the particles 122. For example, the particles 122 are micro-encapsulated bubble-generating agents whose volume swells by a factor of 5 to 10 if water is absorbed. As this type of bubble-generating agent, it is possible to use microspheres obtained by enclosing a substance that generates gas by absorbing water in an elastic capsule. The capsules of the particles 122 can be formed by a material that transmits water, or a water-soluble material, such as a so-called “water-soluble resin”. For example, the material forming the capsules of the particles 122 may be a water-soluble acrylic-based polymer such as sodium polyacrylate or polyacrylamide, polyvinyl alcohol, polyethyleneimine, polyethylene oxide, or polyvinyl pyrrolidone. The particles 122 can be manufactured using coacervation, interfacial polymerization, in-site polymerization, a spray-drying method, a dry-mixing method, or the like.

The material for the particles 122 may be a material that gasifies using water as a solvent, for example, a mixture of sodium hydrogen carbonate (or sodium carbonate) and citric acid, or a mixture of sodium hydrogen carbonate (or sodium carbonate) and fumaric acid.

Alternatively, in another embodiment, the particles 122 are made up of a substance whose volume swells by a factor of 5 to 100 if water is absorbed, for example. For example, such particles may be microspheres that are particles formed from a substance that swells upon absorbing water. The material for the particles 122 may be a so-called water-absorbing polymer such as a starch-based polymer, a cellulose-based polymer, a polyacrylate-based polymer, a polyvinyl alcohol-based polymer, or a polyacrylamide-based polymer, which are obtained by graft polymerization or carboxymethylation. The particles 122 may be a sodium polyacrylate-based polymer having a property of being unlikely to release absorbed water even if pressure is applied.

Alternatively, commercial products may be used as the particles 122. For example, Arasorb (manufactured by Arakawa Chemical Industries, Ltd.), Wondergel (manufactured by Kao Corporation), KI Gel (manufactured by Kuraray Isoprene), Sanwet (manufactured by Sanyo Chemical Industries, Ltd.), Sumika Gel (manufactured by Sumitomo Chemical Co., Ltd.), Lanseal (manufactured by Japan Exlan Co., Ltd.), Aquareserve GP (manufactured by Nippon Shokubai Co., Ltd.), Diawet (manufactured by Mitsubishi Chemical Corporation), Water Lock (manufactured by Grain Processing Corporation), or Aqualon (manufactured by Hercules Incorporated) may be used. Also, Vargas 700 (manufactured by Lion Corporation), Aqua Keep TM (a polyacrylate-based super-absorbent resin) (manufactured by Sumitomo Seika Chemicals Co., Ltd.), or the like may be used.

The particle size of the particles 122 may be 1 to 80 μm, and in particular may be 3 to 50 μm. The amount of bubble generation to be performed by the particles 122 can be set by adjusting the type and amount of the material enclosed in the capsules. Also, the particles 122 may have an appropriate degree of strength such that they not rupture until the volume expansion coefficient reaches 5 or above, and in particular 10 or above. Due to having such a strength, the adhesive force between the sensor panel 110 and the scintillator layer 120 can be efficiently weakened if the particles 122 expand by being heated or by absorbing water.

The temperature at which the particles 122, which can expand due to heating, start bubble generation can be set by adjusting the type of substance included in the capsules. The temperature at which the particles 122 included in the scintillator layer 120 of the radiation detection apparatus 100 start bubble generation may be set to 60 to 170° C., and in particular it may be set to 100 to 170° C. for example. Also, the color of the particles 122 may be colorless and transparent so as not to influence the detection of light by the sensor panel 110.

The degree to which the adhesive force between the sensor panel 110 and the scintillator layer 120 weakens in the case where the particles 122 expand depends on the amount of particles 122 included in the scintillator layer 120. The amount of particles 122 can be defined by the volume density of the particles 122 in the scintillator layer 120 for example. Below, let β be the expansion coefficient of the particles 122. If the volume density of the particles 122 is less than (400π)/(3β³) %, there will be cases where the adhesive force between the sensor panel 110 and the scintillator layer 120 cannot be sufficiently weakened, even if the particles 122 expand. If the volume density of the particles 122 is greater than or equal to (400π)/(3β³) % and less than (2000π)/(3β³) %, the adhesive force between the sensor panel 110 and the scintillator layer 120 will weaken if the particles 122 expand. However, there are cases where foam spheres resulting from the particles 122 generating bubbles and expanding are not distributed on the entire adhesion surface, and after separating the scintillator layer 120 from the sensor panel 110, resin 123 remains on the sensor panel 110.

If the volume density of the particles 122 is greater than or equal to (2000π)/(3β³) %, the adhesive force between the sensor panel 110 and the scintillator layer 120 will weaken if the particles 122 expand. Furthermore, the foam spheres resulting from the particles 122 generating bubbles and expanding are distributed on the entire adhesion surface, the scintillator layer 120 can be separated easily from the sensor panel 110, and no resin 123 remains on the sensor panel 110.

Additionally, if the volume density of the particles 122 in the scintillator layer 120 exceeds 50%, a sufficient amount of light generated by the scintillator 121 may not arrive at the sensor panel 110 due to being obstructed by the particles 122. As a result of this, the resolution (MTF) of the radiation detection apparatus 100 decreases. In view of this, in order to be able to easily separate the scintillator layer 120 from the sensor panel 110, and in order to secure the resolution of the radiation detection apparatus 100, the volume density of the particles 122 may be set in the range of (2000π)/(3β³) % to 50% inclusive.

The resin 123 functions as a binder for holding the scintillator 121 and the particles 122, and has a function of adhering the scintillator layer 120 to the sensor panel 110. Polyvinyl acetal, polyvinyl alcohol, polyvinyl pyrrolidone, polyvinyl butyral, cellulosic resin, or acrylic resin, which are water- or alcohol-soluble organic resins, can be used as the resin 123. In particular, a polyvinyl acetal resin such as water-soluble S-LEC KW manufactured by Sekisui Chemical Co., ethanol-soluble S-LEC B manufactured by Sekisui Chemical Co., or the like may be used as the resin 123. The resin 123 may be any kind of resin as long as it is a resin that can be used when creating a fluorescent material coating paste, and for example, it possible to use a general-use organic vehicle (binder), examples of which include a cellulose-based resin such as ethylcellulose, nitrocellulose, cellulose acetate butyrate, or cellulose acetate propionate, an acrylic resin, a urethane resin, an epoxy resin, a polyimide resin, a vinyl chloride-vinyl acetate copolymer resin, a polyvinyl butyral resin, a polyvinyl acetal resin, an alkyd resin, a phenol resin, a melamine resin, a urea resin, a rosin resin, and a urea resin high-melting-point fatty acid. Furthermore, it is possible to use one or any combination of these types of resins as the resin 123.

The resin 123 can mitigate stress that occurs between the sensor panel 110 and the scintillator layer 120 in the heating process and the like. This stress can be caused by a difference in thermo-expansion coefficients between the sensor panel 110 and the scintillator layer 120. In the case where the modulus of elasticity in tensile of the resin 123 is less than 0.7 GPa, the adhesive force between the sensor panel 110 and the scintillator layer 120 is insufficient, and there are cases where layer separation occurs. Also, there are cases where the adhesive force of both the scintillator 121 and the particles 122 held by the resin 123 is insufficient and a breakdown in the adhesion between the scintillator 121 and the particles 122 occurs. On the other hand, if the modulus of elasticity in tensile of the resin 123 is 3.5 GPa or higher, there are cases where stress in the scintillator layer 120 cannot be sufficiently absorbed and layer separation occurs. In view of this, the scintillator layer 120 may be formed such that the modulus of elasticity in tensile of the resin 123 is included in the range of greater than or equal to 0.7 GPa to less than 3.5 GPa. Also, the modulus of elasticity in tensile of the resin 123 may be uniform in the entire scintillator layer 120, but it does not need to be uniform. For example, the most intense stress is applied to positions in the proximity of the sensor panel 110, and therefore the scintillator layer 120 may have a distribution such that the modulus of elasticity in tensile of the resin 123 is lowest at positions in the proximity of the sensor panel 110. Also, the density of the particles 122 (e.g., the volume density) in the scintillator layer 120 may also be uniform in the entire scintillator layer 120, but it does not need to be uniform. For example, in order to efficiently weaken the adhesive force between the sensor panel 110 and the scintillator layer 120, there may be a distribution such that the density of the particles 122 is highest in positions that are in the proximity of the sensor panel 110.

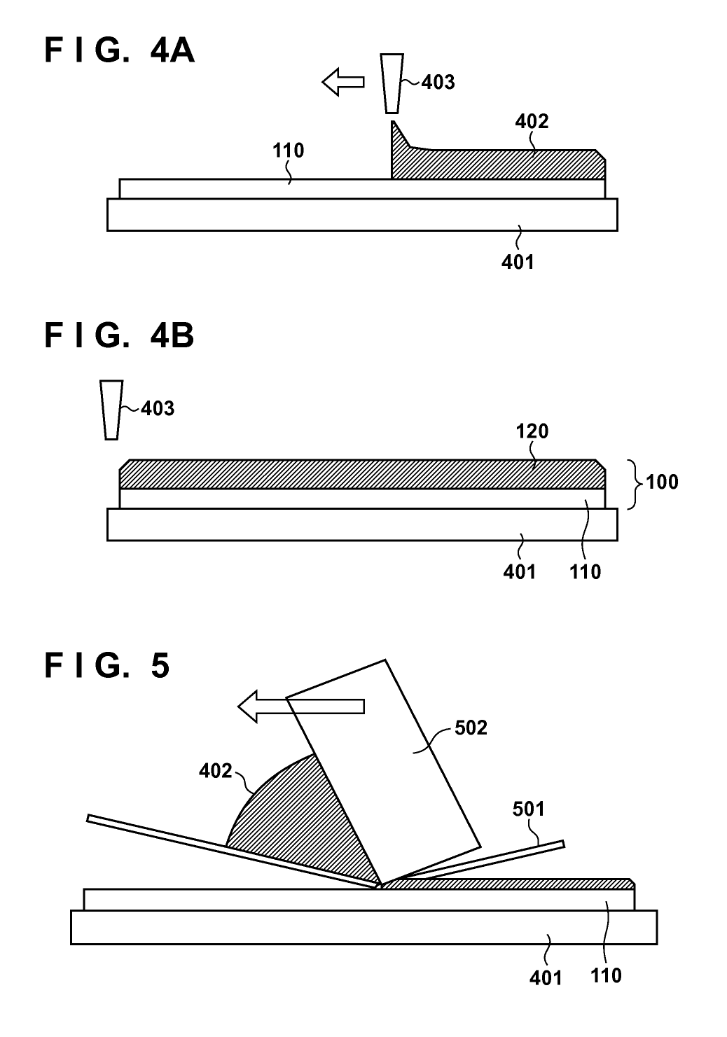

Next, an example of a method of manufacturing the radiation detection apparatus 100 will be described with reference to FIGS. 4A and 4B. In this example, the scintillator layer 120 is formed using a slit-coat method. First, the sensor panel 110 is prepared and fixed to a stage 401. Any kind of technique may be used as the method of manufacturing the sensor panel 110, and since a commonly known technique for example may be used, a detailed description thereof will be omitted. Next, a paste 402 is formed by mixing the scintillator 121, the particles 122, and the resin 123 in an organic solvent called a vehicle. In view of recent environmental problems, a solvent that has a low molecular weight and includes a hyrodxyl group, such as a water- or alcohol-based solvent may be used as the solvent included in the vehicle. Any solvent may be included in the vehicle, as long as it is a solvent that effectively dissolves an organic resin and any other additives therein. As the solvent, it is possible to use: a glycol such as ethylene glycol, propylene glycol, diethylene glycol, or dipropylene glycol; a glycol ether such as ethylene glycol monomethyl ether, ethylene glycol monoethyl ether, ethylene glycol monobutyl ether, ethylene glycol dimethyl ether, ethylene glycol mono-n-hexyl ether, ethylene glycol monoallyl ether, ethylene glycol dodecyl ether, ethylene glycol monoisobutyl ether, ethylene glycol monophenyl ether, ethylene glycol isoamyl ether, ethylene glycol benzyl ether, diethylene glycol monomethyl ether, diethylene glycol monoethyl ether, diethylene glycol monobutyl ether, triethylene glycol monomethyl ether, or triethylene glycol monobutyl ether; a glycol ether such as diethylene glycol dimethyl ether, propylene glycol monomethyl ether, dipropylene glycol monomethyl ether, or tripropylene glycol monomethyl ether, or an acetate thereof; a diester salt of a dibasic acid, such as dimethyl adipate, dimethyl glutarate, or dimethyl succinate; a ketone such as acetone, methyl ethyl ketone, methyl isobutyl ketone, diethyl ketone, methyl amyl ketone, or cyclohexanone; an aromatic such as xylene, toluene, or ethylbenzene; an alcohol such as n-propyl alcohol, isopropyl alcohol, butanol, α-turpineol, β-turpineol, carveol, methanediol, or tridecyl alcohol; an ester such as 2,2,4-trimethyl-1,3-pentanediol mono(2-methylpropanoate), methyl-3-methoxypropionate, ethyl acetate, isopropyl acetate, butyl acetate, isobutyl acetate, methoxybutyl acetate, amyl acetate, isoamyl acetate, cyclohexyl acetate, benxyl acetate, ethyl propionate, butyl propionate, isobutyl propionate, or isoamyl propionate; or a well-known solvent, such as dimethylacetamide, or dimethylformamide. It is possible to use a mixture of two or more of the aforementioned types. Also, in order to improve dispersability and the printability of the paste, an anti-foaming agent, a thixotropy agent, a leveling agent, and a dispersion agent can be added to the solvent in some embodiments. Then, as shown in FIG. 4A, the paste 402 is emitted from a die coater 403 in a scanning motion to coat the upper surface of the sensor panel 110.

When coating with the paste 402 at a position that covers the pixel array of the sensor panel 110 is complete, the paste 402 is heated and dried, thus eliminating the organic solvent and curing the paste 402. If the particles 122 are composed of a substance that can expand upon being heated, this heating is performed using a temperature that is lower than the temperature at which the particles 122 start generating bubbles, such as a temperature of 80 to 150° C. Thus, as shown in FIG. 4B, the scintillator layer 120, which includes the scintillator 121, the particles 122, and the resin 123, is formed, and the radiation detection apparatus 100 is obtained.

In the embodiment described above, the scintillator layer 120, which includes a mixture of the scintillator 121 and the particles 122, was formed by mixing the particles 122 into the paste 402, but such a scintillator layer 120 may be formed by other methods. For example, after the particles 122 are arranged on the sensor panel 110, a paste formed by mixing the scintillator 121 and the resin 123 into an organic solvent may be used to coat the particles 122 and the sensor panel 110. The scintillator layer 120 formed in such a manner includes a mixture of the scintillator 121 and the particles 122 only in portions that are in the proximity of the sensor panel 110, and the particles 122 are not included in portions that are away from the sensor panel 110. In this case as well, the adhesive force between the sensor panel 110 and the scintillator layer 120 can be weakened by causing the particles 122 to generate bubbles. Furthermore, a configuration is possible in which the step of applying paste is performed multiple times, and the type of paste is changed in any of these steps. For example, the type of paste may be changed by mixing the scintillator 121, the particles 122, and the resin 123 at a different ratio into the solvent, and the type of paste may be changed by changing the materials of the various elements of the paste. Thus, the scintillator layer 120 can be formed such that the modulus of elasticity in tensile of the resin 123 is not uniform. Also, in the aforementioned embodiment, the resin 123 was cured by drying, but if a light curable resin is used as the resin 123, the resin 123 may be cured by irradiating the applied paste 402 with light.

Next, another example of a method of manufacturing the radiation detection apparatus 100 will be described with reference to FIG. 5. In this example, the scintillator layer 120 is formed using a screen printing method. Similarly to the case of the slit-coat method, the sensor panel 110 is prepared and fixed to the stage 401. A mesh board 501 is placed on the sensor panel 110, and the paste 402 is placed on the mesh board 501. The paste used in the screen printing method may be the same as the aforementioned paste 402 used in the slit-coat method. Then, as shown in FIG. 5, the paste 402 is emitted uniformly from the openings of the mesh board 501 by pressing a squeegee 502 against the mesh board 501 and performing a scanning motion so as to coat the sensor panel 110. Subsequently, similarly to the case of the slit-coat method, the paste 402 is heated and dried, thus eliminating the organic solvent and curing the paste 402. Accordingly, the radiation detection sensor 100 is obtained. Even in the case where the screen printing method is used, similarly to the case of the slit-coat method, a configuration is possible in which different types of paste are applied multiple times, and a configuration is possible in which the particles 122 are arranged on the sensor panel 110 and then the particles 122 are coated with the paste.

In the case where the scintillator layer 120 is to be separated from the radiation detection apparatus 100 manufactured as described above, for example, the particles 122 are heated to a temperature that is higher than the temperature at which the particles 122 start generating bubbles, and the adhesive force between the sensor panel 110 and the scintillator layer 120 is weakened. Alternatively, by adding water to the fluorescent material containing the particles 122, the particles generate bubbles or swell, and the adhesive force between the sensor panel 110 and the scintillator layer 120 is weakened. Subsequently, the scintillator layer 120 may be removed from the sensor panel 110.

In the example described above, the scintillator 121 was in particle form, but the scintillator 121 may be in column form. In the case of the columnar scintillator 121, first, the scintillator 121 is formed on the sensor panel 110 by vapor deposition. Subsequently, a paste including the particles 122 and the resin 123 is poured between the columns of the scintillator 121, and the scintillator layer 120 is formed by drying the paste.

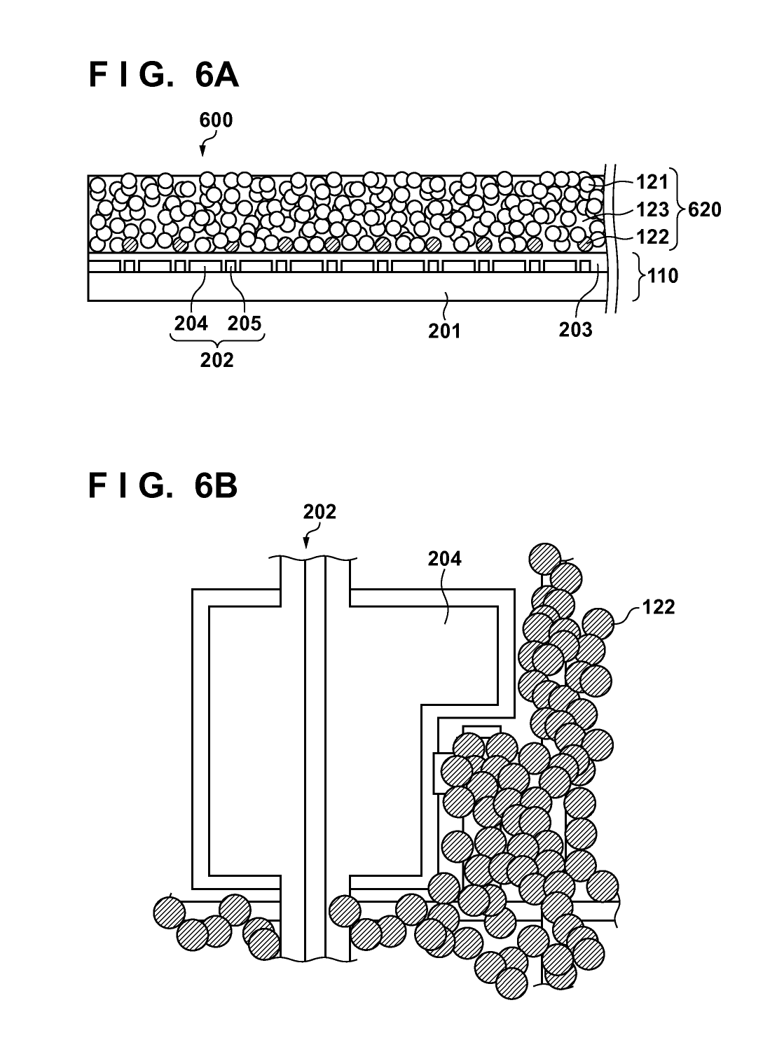

Next, a structure of a radiation detection apparatus 600 according to some other embodiments of the present invention will be described with reference to FIGS. 6A and 6B. The radiation detection apparatus 600 has the sensor panel 110 and a scintillator layer 620, and FIG. 6A shows a cross-sectional view of them. In the present embodiment as well, the scintillator layer 620 is formed directly on the sensor panel 110. The various variations described in the embodiment shown in FIG. 1 can be applied similarly to the present embodiment as well.

Similarly to the scintillator layer 120, the scintillator layer 620 includes the scintillator 121, the particles 122, and the resin 123, but the arrangement of the particles 122 in the scintillator layer 620 is different from that in the scintillator layer 120. As shown in detail in the plan view in FIG. 6B, in the pixel 202, the particles 122 are not arranged on portions covering the photoelectric converters 204, and are arranged on portions covering the circuits 205, which are included in portions other than those that include the photoelectric converters 204. In the example of the pixels 202 according to the present embodiment, the particles 122 are arranged on portions that cover the TFT 301, the gate line 302, and the signal line 303. Due to not arranging the particles 122 on portions that cover the photoelectric converters 204 in this way, the particles 122 are prevented from obstructing the light emitted onto the photoelectric converters 204. Also, light that is incident on the TFTs 301, the gate lines 302, and the signal lines 303 is not converted into an electric charge, and therefore the operation of the radiation detection apparatus 600 is not influenced even if these portions are covered by the particles 122. Particles having a diameter of 1 μm to 30 μm for example may be selected such that the diameter of the particles 122 is smaller than the width of the gate line 302 and the signal line 303.

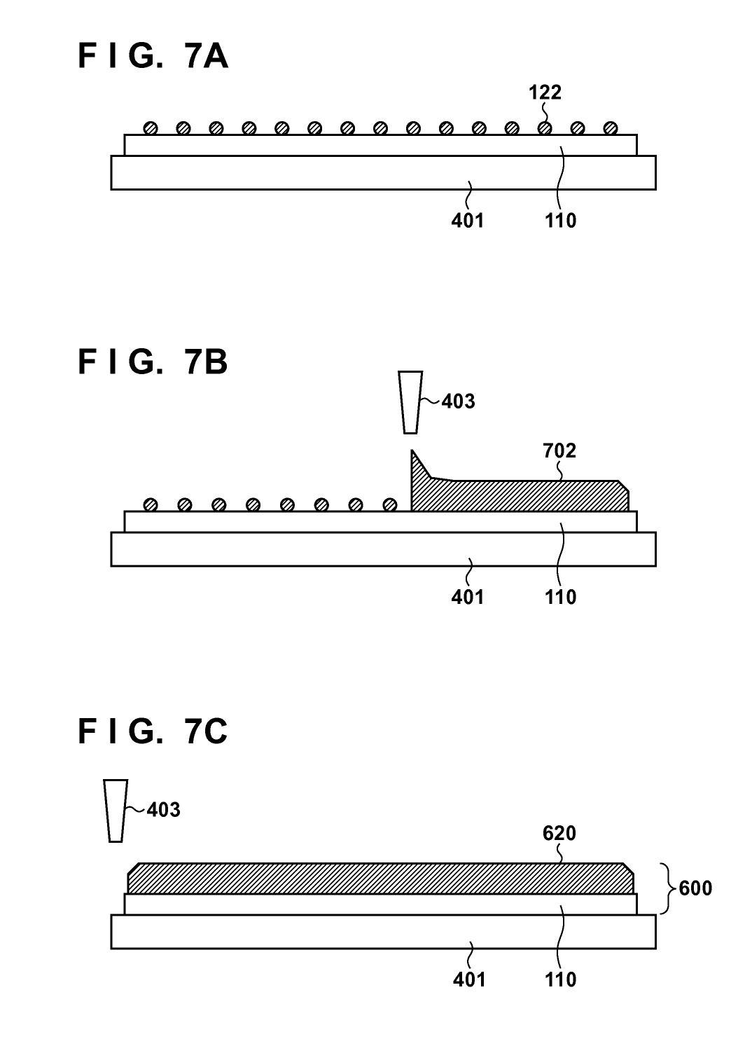

Next, an example of a method of manufacturing the radiation detection apparatus 600 will be described with reference to FIGS. 7A to 7C. In this example, the scintillator layer 620 is formed using the slit-coat method. First, the sensor panel 110 is prepared and fixed to the stage 401. Next, as shown in FIG. 7A, the particles 122 are arranged at positions that cover the circuits 205. They may be arranged directly, arranged by emission from a needle or the like at positions aligned by an apparatus, or arranged using a mask/slits. A paste 702 is created by mixing the scintillator 121 and the resin 123 into an organic solvent called a vehicle. The particles 122 are not included in the paste 702. In view of recent environmental problems, a solvent that has a low molecular weight and includes a hydroxyl group, such as a water- or alcohol-based solvent may be used as the solvent included in the vehicle. Then, as shown in FIG. 7B, the paste 702 is emitted from the die coater 403 in a scanning motion so as to coat the upper surface of the sensor panel 110.

When coating with the paste 702 at a position that covers the pixel array of the sensor panel 110 is complete, the paste 702 is heated and dried, thus eliminating the organic solvent and curing the paste 702. This heating is performed at a temperature that is lower than the temperature at which the particles 122 start generating bubbles, such as a temperature of 80 to 150° C. Thus, as shown in FIG. 7C, the scintillator layer 620 that includes the scintillator 121, the particles 122, and the resin 123 is formed, and the radiation detection apparatus 600 is obtained. In FIGS. 7A to 7C, a method of manufacturing using the slit-coat method is shown, but manufacturing can be performed similarly using a screen printing method as well, similarly to the embodiment described with reference to FIG. 1.

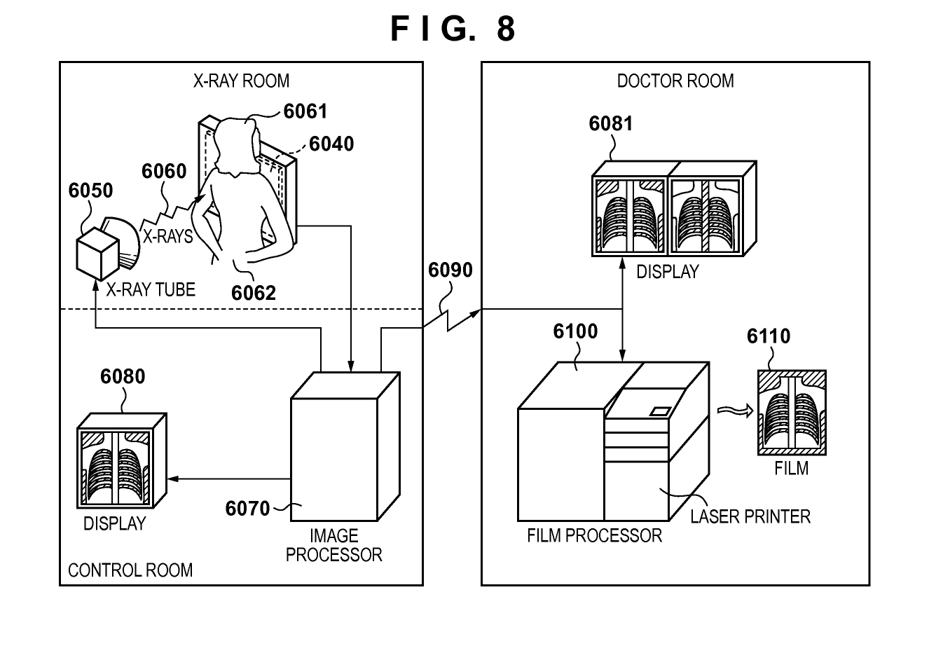

FIG. 8 shows an example where a radiation detection apparatus according to the present invention is applied to an X-ray diagnosis system (radiation detection system). X-rays 6060 generated by an X-ray tube 6050 pass through a chest region 6062 of a patient or test subject 6061 and enter a radiation detection apparatus (image sensor) 6040 such as the one shown in FIG. 1. Information regarding the interior of the body of the patient 6061 is included in these input X-rays. A scintillator emits light in response to the input of X-rays, this light is photoelectrically converted by photoelectric converters in the sensor panel, and electrical information is obtained. This information is digitally converted, undergoes image processing by an image processor 6070 functioning as a signal processing unit, and can then be observed with a display 6080 functioning as a display unit in a control room. Also, this information can be transferred to a remote location by a transmission processing unit such as a network 6090, exemplified by a telephone, a LAN, the Internet, or the like. As a result, the information can be displayed on a display 6081 functioning as a display unit in a doctor's room or the like in another location, or it can be stored on a recording unit such as an optical disk or the like, and a doctor in a remote location can also give a diagnosis. Also, the information can be recorded on a film 6110 using a film processor 6100 that functions as a recording unit.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application Nos. 2012-170377 filed Jul. 31, 2012 and 2013-148831 filed Jul. 17, 2013, which are hereby incorporated by reference herein in their entirety.

What is claimed is:

1. A radiation detection apparatus comprising:
a sensor panel configured to detect light; and
a scintillator layer arranged on the sensor panel, the scintillator layer having:
a scintillator configured to convert radiation into light of a wavelength that is detectable by the sensor panel;
particles that have a property of generating a bubble and expanding so as to weaken adhesive force between the sensor panel and the scintillator layer; and
a resin that holds the scintillator and the particles so as to be mixed together,
wherein the scintillator layer is adhered to the sensor panel with use of the resin.

2. The apparatus according to claim 1, wherein
the particles have a property of generating bubbles and expanding due to heat.

3. The apparatus according to claim 1, wherein
the particles have a property of generating bubbles or swelling due to water absorption.

4. The apparatus according to claim 1, wherein
the sensor panel has a plurality of pixels, each pixel having a photoelectric conversion unit configured to detect light and having another portion, and
the particles are not arranged at a position that covers the photoelectric conversion unit, and are arranged at a position that covers the other portion.

5. The apparatus according to claim 1, wherein
a density of the particles in the scintillator layer is higher in proximity to the sensor panel.

6. The apparatus according to claim 1, wherein
a modulus of elasticity in tensile of the resin is lower in proximity to the sensor panel.

7. The apparatus according to claim 1, wherein
the scintillator includes gadolinium sulfate in particle form.

8. A method of manufacturing a radiation detection apparatus comprising:
preparing a sensor panel configured to detect light; and
forming a scintillator layer directly on the sensor panel,
the scintillator layer having:
a scintillator configured to convert radiation into light of a wavelength that is detectable by the sensor panel;
particles that have a property of generating bubbles and expanding so as to weaken adhesive force between the sensor panel and the scintillator layer; and
a resin that holds the scintillator and the particles so as to be mixed together,
wherein in the forming, the scintillator layer is adhered to the sensor panel with use of the resin.

9. The method according to claim 8, wherein
the forming includes
arranging the particles on the sensor panel,
coating the sensor panel and the particles with a paste that includes a mixture of the scintillator and the resin, and
curing the paste.

10. The method according to claim 9, wherein
the sensor panel to be prepared in the preparation step has a plurality of pixels, each pixel having a photoelectric conversion unit configured to detect light and having another portion, and
in the arranging, the particles are not arranged above the photoelectric conversion unit, and the particles are arranged above the other portion.

11. The method according to claim 8, wherein
the forming includes
coating the sensor panel with a paste that includes a mixture of the particles, the scintillator, and the resin, and
curing the paste.

12. A radiation detection system comprising:
the radiation detection apparatus according to claim 1; and
a processing unit configured to process a signal from the radiation detection apparatus.
